(19) United States
(12) Patent Application Publication
(10) Pub. No.: US 2026/0346374 A1
(43) Pub. Date: Nov. 5, 2026

(54) LASER HEAT TREATMENT METHOD FOR SUBSTRATE STRUCTURE, AND METHOD FOR MANUFACTURING ELECTRONIC ELEMENT BY APPLYING SAME

(71) Applicant: RNR LAB INC., Yongin-si, Gyeonggi-do (KR)

(72) Inventors: Jeong Do RYU, Seoul (KR); Joo Hyun CHO, Yongin-si, Gyeonggi-do (KR); Sung Hoon RYU, Yangyang-gun, Gangwon-do (KR)

(73) Assignee: RNR LAB INC., Yongin-si, Gyeonggi-do (KR)

(21) Appl. No.: 19/485,684

(22) PCT Filed: Apr. 22, 2024
(86) PCT No.: PCT/KR2024/005400

§ 371 Date: Nov. 19, 2025

(30) Foreign Application Priority Data
May 24, 2023 (KR) 10-2023-0067269

(51) Int. Cl. B23K 26/352; B23K 26/08; B23K 26/082; B23K 101/40; H10P 34/42

(52) U.S. Cl. CPC B23K 26/352; B23K 26/082; B23K 26/083; H10P 34/42; B23K 2101/40

(57) ABSTRACT

A laser heat treatment method for a substrate structure and a method for manufacturing an electronic device using the same are disclosed. The disclosed laser heat treatment method for a substrate structure is a laser heat treatment method for performing a heat treatment on the substrate structure by irradiating a laser beam on a first surface of the substrate structure compartmentalizable into a plurality of unit regions, wherein the laser heat treatment method may include the step of performing an n-th laser heat treatment on the substrate structure and the step of performing an (n+1)-th laser heat treatment on the substrate structure, wherein the n-th laser heat treatment may be performed on a first region comprising one or more of the unit regions in the substrate structure. The (n+1)-th laser heat treatment may be performed on a second region comprising one or more the unit regions in the substrate structure.

### TECHNICAL FIELD

The present invention relates to a heat treatment method for a workpiece and a manufacturing method for an electronic device applied thereto, and more particularly to a laser heat treatment method for a substrate structure and a manufacturing method for an electronic device applied thereto.

### BACKGROUND ART

In general, a semiconductor device/electronic device may be manufactured by a plurality of processes. For example, processes for manufacturing semiconductor devices/electronic devices may include a thin film deposition process, a photolithography process, an etching process, an ion implantation process, a heat treatment (i.e., annealing) process, and the like. Among these, the heat treatment process may be a process for stabilizing, activating, or melting a substrate or a thin film formed on the substrate, or for removing defects such as seams in the thin film, so as to improve and secure the characteristics of the device. The heat treatment (annealing) process may include a laser heat treatment process, a rapid thermal process (RTP), or the like.

The laser annealing process has the advantage of being able to perform heat treatment mainly on the surface of the substrate or an area adjacent thereto using a laser, thus having less impact on other processes, reducing heat damage, and being relatively easy to heat up and control. However, as the integration density of semiconductor devices/electronic devices improves, the size of unit devices continues to shrink, and the process becomes more sophisticated, the temperature unevenness generated on the substrate during laser heat treatment may cause various problems in the manufacturing characteristics of the device.

In addition, in order to irradiate the laser in a constant shot area according to a stepper method in a conventional laser heat treatment process, it is necessary to ensure uniform laser energy over a relatively wide range to match the size of the shot area, which requires the application of a complex optical system. The use of complex optics not only increases the cost of the equipment, but may also be disadvantageous in terms of maintenance and management.

Therefore, there is a need for a laser heat treatment method and related technology that may not only improve heat treatment characteristics by easily controlling temperature distribution, but also reduce equipment costs and maintenance burden by simplifying the applied optical system.

### DISCLOSURE OF THE INVENTION

### Technical Problem

The technical challenge of the present invention is to provide a laser heat treatment method that may easily control the temperature dispersion during heat treatment with a laser to improve the heat treatment characteristics.

Furthermore, the technical problem of the present invention is to provide a laser heat treatment method that may reduce equipment costs and maintenance burden by simplifying the optical system applied in heat treatment using a laser.

Furthermore, a technical problem to be solved by the present invention is to provide a method for manufacturing an electronic device (semiconductor device) by applying the aforementioned laser heat treatment method.

The problems to be solved by the present invention are not limited to those mentioned above, and other problems not mentioned may be understood by those skilled in the art from the following description.

### Technical Solution

According to one embodiment of the present invention, a laser heat treatment method for performing a heat treatment on one surface of a substrate structure by irradiating a laser beam on a first surface of a substrate structure compartmentalizable into a plurality of unit regions, the laser heat treatment method comprising: performing an n-th laser heat treatment on the substrate structure; and performing an (n+1)-th laser annealing on the substrate structure, wherein the n-th laser annealing is performed on a first region comprising one or more the unit regions in the substrate structure, and wherein the (n+1)-th laser annealing is performed on a second region comprising one or more the unit regions in the substrate structure, wherein the step of performing the n-th laser annealing comprises irradiating the first region with the laser beam in a scanning manner while varying a relative position between the substrate structure and the laser beam, and wherein the step of performing the (n+1)-th laser annealing comprises irradiating the second region with the laser beam in a scanning manner while varying a relative position between the substrate structure and the laser beam.

Each of the n-th laser heat treatment and the (n+1)-th laser heat treatment may be performed in a raster scan manner while moving a stage on which the substrate structure is disposed.

A scan direction width of the laser beam of each of the first region and the second region may be smaller than a scan-direction width of the substrate structure.

The first region and the second region may be spaced apart from each other.

The plurality of unit regions may be arranged to form a plurality of rows in a first direction and a plurality of columns in a second direction perpendicular to the first direction, and the first region and the second region may be spaced apart from each other in any one of the first direction, the second direction, and a third direction between the first direction and the second direction.

The spacing between the first region and the second region may be at least about 90% of a width of the unit region in either the first direction and the second direction.

The first region and the second region may be in contact with each other.

The first region and the second region may have different sizes.

The first region and the second region may have the same size.

The laser heat treatment method may comprise the step of performing an (n+m)-th laser heat treatment on the substrate structure, wherein m is an integer greater than 2, wherein the (n+m)-th laser heat treatment may be performed on a third region of the substrate structure, wherein the third region may be located on a side of one of the first region and the second region, or may be located between the first region and the second region.

The laser heat treatment method may be performed over the entire effective area of the one surface of the substrate structure.

The laser beam may have a width in the range of about 1 μm to 500 μm.

The laser beam may comprise any one of ultraviolet ray, visible ray, infrared ray, and microwave.

The substrate structure may comprise a semiconductor film or an insulator film, and the thermal treatment with the laser may be performed to change the crystallinity, physical properties, or film quality of the semiconductor film or insulator film.

The substrate structure may comprise a wafer.

Before performing the heat treatment with the laser beam, the substrate structure may have an initial temperature of about 550 °C or less, and the heating temperature of the corresponding region of the substrate structure by irradiation of the laser beam may be in the range of about 200 to 3000 °C.

According to another embodiment of the present invention, there is provided a method for manufacturing an electronic device, comprising: heat treating a substrate structure using the aforementioned laser heat treatment method; and manufacturing an electronic device from the heat treated substrate structure.

### Advantageous Effects

According to embodiments of the present invention, a laser heat treatment method may be implemented that may easily control the temperature dispersion during heat treatment using a laser to improve heat treatment characteristics. Furthermore, according to embodiments of the present invention, it is possible to implement a laser heat treatment method that may simplify the optical system applied in heat treatment with a laser, thereby reducing equipment costs and reducing the maintenance burden.

By applying the laser heat treatment method according to embodiments of the present invention, it may be possible to manufacture electronic devices (semiconductor devices) having excellent performance and uniformity.

However, the effects of the present invention are not limited to the above effects, and may be expanded in various ways without departing from the technical ideas and scope of the present invention.

### BRIEF DESCRIPTION OF THE DRAWINGS

FIG. 1 is a plan view to illustrate a method of laser heat treatment of a substrate structure, in accordance with one embodiment of the present invention.

FIG. 2 is a plan view to exemplarily illustrate a laser heat treatment method for a first region of the substrate structure of FIG. 1, in accordance with one embodiment of the present invention.

FIG. 3 is a plan view to exemplarily illustrate a laser heat treatment method for a second region of the substrate structure of FIG. 1, according to one embodiment of the present invention.

FIG. 4 is a plan view to exemplarily illustrate a laser heat treatment method for the second region of the substrate structure of FIG. 1, according to another embodiment of the present invention.

FIGS. 5a to 5c are plan views to illustrate a laser heat treatment method for a substrate structure, according to another embodiment of the present invention.

FIGS. 6a to 6c are plan views to illustrate a laser heat treatment method for a substrate structure, according to another embodiment of the present invention.

FIGS. 7a to 7c are plan views to illustrate a method of laser heat treating a substrate structure, according to a first comparative example.

FIG. 8 is a plan view to illustrate a laser heat treatment method for a substrate structure, according to a second comparative example.

FIG. 9 is a perspective view to illustrate a manufacturing method of an electronic device using a laser heat treatment method for a substrate structure according to an embodiment of the present invention.

### BEST MODE FOR CARRYING OUT THE INVENTION

Hereinafter, embodiments of the present invention will be described in detail with reference to the accompanying drawings.

The embodiments of the invention to be described below are provided for the purpose of explaining the invention more clearly to those having ordinary knowledge in the art, and the scope of the invention is not limited by the following embodiments, and the following embodiments may be modified in various other forms.

The terms used herein are intended to describe specific embodiments and are not intended to limit the invention. Terms used herein in the singular form may include the plural form, unless the context clearly indicates otherwise. Furthermore, the terms “comprise” and/or “comprising” as used herein are intended to specify the presence of the mentioned shapes, steps, numbers, motions, absences, elements, and/or groups thereof, and are not intended to exclude the presence or addition of one or more other shapes, steps, numbers, motions, absences, elements, and/or groups thereof. Furthermore, as used herein, the term “connected” is intended to mean not only that certain elements are directly connected, but also that they are indirectly connected by the interposition of other elements between them.

Furthermore, when the present disclosure refers to a member being located “on” another member, this includes not only when a member abuts another member, but also when there is another member between the two members. As used herein, the term “and/or” includes any one of the enumerated items and any combination of one or more of them. In addition, the terms “about,” “substantially,” and the like as used in the disclosure are intended to mean at or near the range of numbers or degrees, taking into account inherent manufacturing and material tolerances, and to prevent infringers from taking unfair advantage of the disclosure where precise or absolute numbers are stated, which are provided for the purpose of illustration.

Embodiments of the present invention will now be described in detail with reference to the accompanying drawings. The sizes or thicknesses of the areas or parts shown in the accompanying drawings may be somewhat exaggerated for clarity and ease of description. Throughout the detailed description, like reference numerals designate like components.

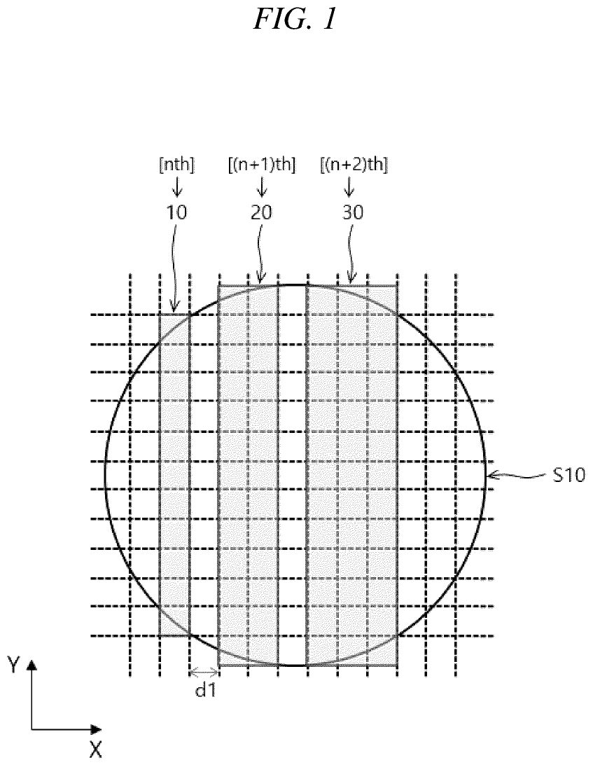

FIG. 1 is a plan view to illustrate a method of laser thermal processing of a substrate structure, in accordance with one embodiment of the present disclosure.

Referring to FIG. 1, a laser heat treatment method for a substrate structure according to an embodiment of the present invention may be a laser heat treatment method (i.e., a laser annealing method) for performing heat treatment (i.e., annealing) on a substrate structure S10 by irradiating a laser beam on a first surface of the substrate structure S10 compartmentalizable into a plurality of unit regions. The substrate structure S10 may include a semiconductor substrate, an insulating substrate, or, in some cases, a conductive substrate. The substrate structure S10 may further include an element portion comprising a predetermined thin film or a thin film formed on the substrate (base substrate). As a non-limiting example, the semiconductor substrate may include at least one of various semiconductor materials comprising Si, Ge, SiGe, SiC, GaN, GaAs, and the like. The thin film may comprise at least one of a semiconductor thin film, an insulator thin film, and a conductive thin film. The semiconductor thin film may comprise various semiconductor materials including amorphous silicon, polycrystalline silicon, and the like. The insulator thin film may include silicon oxide, silicon nitride, silicon nitride oxide, a high-k material having a higher dielectric constant than silicon nitride, and the like. The conductive thin film may comprise at least one of, e.g., a metal, a metal compound. The device portion may include, as a non-limiting example, a switching element such as a transistor or diode, a storage node, or a memory element such as a capacitor or a resistive layer. Further, the substrate structure S10 may include a wafer or have a wafer shape.

If the substrate structure S10 includes a semiconductor film or an insulator film, the heat treatment using the laser may be performed to change the crystallinity, physical properties, or film quality of the semiconductor film or insulator film. As a non-limiting example, the laser thermal treatment may be performed to crystallize amorphous silicon, to remove defects such as seams in the film, to activate doping regions, or to stabilize the substrate or film. In addition, heat treatment with the laser may be performed for various other purposes.

The plurality of regions on one side of the substrate structure S10 delimited by the grid of dotted lines shown in FIG. 1 may correspond to the plurality of unit regions described above. One grid region (square region) formed by the dotted lines in FIG. 1 may correspond to the unit region. The unit area may correspond to a shot area that is simultaneously irradiated by a laser at one time in laser heat treatment according to a conventional stepper method. However, in embodiments of the present invention, the unit area may not be irradiated with a laser in a shot manner. The unit area may have, for example, a square shape or a substantially square shape. By irradiating the plurality of unit areas on one side of the substrate structure S10 with a laser beam in a scanning manner according to an embodiment of the present invention, heat treatment (i.e., annealing) of the entire effective area of the one side may be performed.

The laser heat treatment method may comprise the step of performing an n-th laser heat treatment on the substrate structure S10 and the step of performing an (n+1)-th laser heat treatment on the substrate structure S10. The n-th laser heat treatment may be performed on a first region (10) comprising one or more the unit regions in the substrate structure (S10), and the (n+1)-th laser heat treatment may be performed on a second region (20) comprising one or more the unit regions in the substrate structure (S10). Here, n means an integer of 1 or more. Each of the first region 10 and the second region 20 may have a square, rectangular, or square-like shape.

According to one embodiment, the first region 10 and the second region 20 may be spaced apart from each other. The plurality of unit areas may be arranged to form a plurality of rows in a first direction (e.g., the X-axis direction in the drawing) and a plurality of columns in a second direction (e.g., the Y-axis direction in the drawing) perpendicular to the first direction. In this case, the first region 10 and the second region 20 may be spaced apart from each other in any one of the first direction (X-axis direction), the second direction (Y-axis direction), and a third direction between the first direction and the second direction. The distance d1 between the first region 10 and the second region 20 may be a distance corresponding to about 90% or more of a width along any one of the first direction (X-axis direction) and the second direction (Y-axis direction) of the unit area. The distance d1 between the first region 10 and the second region 20 may be at least about 90% of a width along at least one of the first direction (X-axis direction) and the second direction (Y-axis direction) of the unit area, and may be at least about 2000% or less, as a non-limiting example. However, in some cases, it may be greater than about 2000%. As used herein, the term “spacing” may refer to a minimum spacing (minimum distance). This may also be true elsewhere in this specification. In a laser heat treatment method according to one embodiment of the present invention, the n-th laser heat treatment and the (n+1)-th laser heat treatment may be spatially (regionally) spaced apart.

In the embodiment of FIG. 1, the first region 10 and the second region 20 are spaced apart from each other in the first direction (X-axis direction), and a spacing d1 between the first region 10 and the second region 20 is at least about 90% of a width along the first direction (X-axis direction) of the unit area. The unit area may, for example, have a width in the first direction (X-axis direction) of from a few millimeters to a few tens of millimeters and a width in the second direction (Y-axis direction) of from a few millimeters to a few tens of millimeters.

When the first region 10 and the second region 20 are mutually spaced apart in any one of the first direction (X-axis direction) and the second direction (Y-axis direction), the spacing d1 between the first region 10 and the second region 20 may have a distance corresponding to N times the width along any one of the first direction (X-axis direction) and the second direction (Y-axis direction) of the unit area, wherein the N may be an integer greater than or equal to 1. FIG. 1 illustrates a case in which the first region 10 and the second region 20 are spaced apart from each other in the first direction (X-axis direction), and the spacing d1 between the first region 10 and the second region 20 has a distance corresponding to 1 time the width along the first direction (X-axis direction) of the unit area. However, it is also possible to have a spacing of more than twice (two spacing) instead of one (one spacing).

In this way, when the the n-th laser heat treatment and the the (n+1)-th laser heat treatment are spatially (regionally) spaced apart, the effect of suppressing the temperature inhomogeneity of the substrate structure S10 at each laser heat treatment step may be improved.

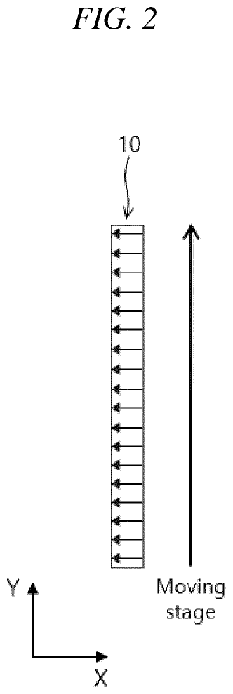

In an embodiment of the present invention, the step of performing the n-th laser heat treatment may include the step of irradiating the first region S10 with the laser beam in a scanning manner while varying the relative position between the substrate structure S10 and the laser beam. Further, the step of performing the (n+1)-th laser heat treatment may comprise the step of irradiating the laser beam in a scanning manner on the second region 20 while varying the relative position between the substrate structure S10 and the laser beam. Each of the n-th laser heat treatment and the (n+1)-th laser heat treatment may be performed in a raster scan manner while moving a stage on which the substrate structure S10 is disposed. In the raster scan method, an operation of scanning the laser beam in one direction while moving the stage may be performed. This will be described in more detail hereinafter with reference to FIGS. 2 to 4.

According to one embodiment, the width along the scanning direction of the laser beam of each of the first region 10 and the second region 20 may be smaller than the width along the scanning direction of the substrate structure S10. As a non-limiting example, the scan direction of the laser beam may be parallel to the X-axis direction. In this case, the width along the X-axis direction of each of the first region 10 and the second region 20 may be smaller than the width along the X-axis direction of the substrate structure S10. As a non-limiting example, the width along the X-axis direction of each of the first region 10 and the second region 20 may be less than about ⅔ of the width along the X-axis direction of the substrate structure S10, or less than about ½, or less than about ⅓.

According to one embodiment, the first region 10 and the second region 20 may have different sizes. In this case, a width along the X-axis direction of the first region 10 may be different from a width along the X-axis direction of the second region 20, and/or a width along the Y-axis direction of the first region 10 may be different from a width along the Y-axis direction of the second region 20. Laser annealing of a plurality of regions 10, 20 having different sizes may be easily accomplished. However, in some cases, the first region 10 and the second region 20 may have the same size.

Further, the laser annealing method may further comprise the step of performing an n+2nd laser annealing on the substrate structure S10. The n+2nd laser heat treatment may be performed on a third region 30 comprising one or more of the unit regions in the substrate structure S10. The third region 30 may be located on one side of any one of the first region 10 and the second region 20. In this embodiment, a case is shown where the third region 30 is located on one side of the second region 20, and the second region 20 is disposed between the first region 10 and the third region 30. Additionally, the third region 30 may be spaced apart from at least one of the first region 10 and the second region 20. In this embodiment, the third region 30 may be spaced apart from the second region 20 to one side of the second region 20, wherein the spacing between the third region 30 and the second region 20 may be a distance corresponding to at least about 90% of the width along at least one of the first direction (X-axis direction) and the second direction (Y-axis direction) of the unit area.

In FIG. 1, the third region 30 and the second region 20 are spaced apart from each other in the first direction (X-axis direction), and a distance between the third region 30 and the second region 20 is at least about 90% of a width along the first direction (X-axis direction) of the unit area. When the third region 30 and the second region 20 are mutually spaced apart in any one of the first direction (X-axis direction) and the second direction (Y-axis direction), the spacing between the third region 30 and the second region 20 may have a distance corresponding to N times the width along any one of the first direction (X-axis direction) and the second direction (Y-axis direction) of the unit area, wherein the N may be an integer greater than or equal to one.

In embodiments of the present invention, the step of performing the n+2nd laser heat treatment may comprise irradiating the third region 30 with the laser beam in a scanning manner while varying the relative position between the substrate structure S10 and the laser beam. The n+2nd laser heat treatment may be performed in a raster scan manner while moving the stage on which the substrate structure S10 is disposed. According to one embodiment, the width along the scan direction of the laser beam of the third region 30 may be smaller than the width along the scan direction of the substrate structure S10. As a non-limiting example, the scan direction of the laser beam may be parallel to the X-axis direction. In this case, the width along the X-axis direction of the third region 30 may be smaller than the width along the X-axis direction of the substrate structure S10. As a non-limiting example, the width along the X-axis direction of the third region 30 may be less than about ⅔ of the width along the X-axis direction of the substrate structure S10, or less than about ½, or less than about ⅓.

According to one embodiment, the third region 30 may have a different size than at least one of the first region 10 and the second region 20. However, in some cases, the third region 30 may have the same size as at least one of the first region 10 and the second region 20.

FIG. 2 is a plan view to exemplarily illustrate a laser heat treatment method for the first region 10 of the substrate structure S10 of FIG. 1, according to one embodiment of the present invention.

Referring to FIG. 2, the step of performing the n-th laser heat treatment may comprise irradiating the first region 10 with the laser beam in a scanning manner while varying the relative position between the substrate structure (S10 of FIG. 1) and the laser beam. The n-th laser heat treatment may be performed in a raster scan manner while moving a stage on which the substrate structure (S10 in FIG. 1) is disposed. In the raster scan method, the laser beam may be scanned in one direction while moving the stage. The blue arrow indicates the scanning direction of the laser beam. The scanning direction of the laser beam may be, for example, parallel to the X-axis direction. The direction of movement of the stage may be parallel to the Y-axis direction, for example.

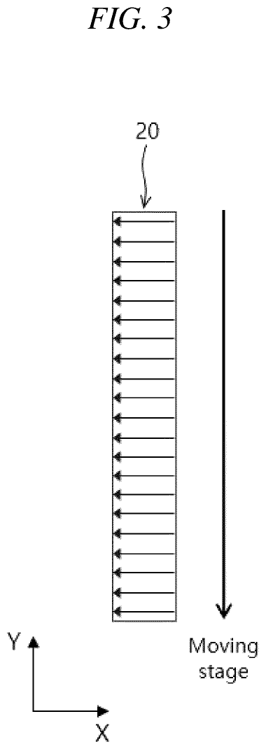

FIG. 3 is a plan view to exemplarily illustrate a laser heat treatment method for the second region 20 of the substrate structure S10 of FIG. 1, according to one embodiment of the present invention.

Referring to FIG. 3, the step of performing the (n+1)-th laser heat treatment may comprise irradiating the second region 20 with the laser beam in a scanning manner while varying the relative position between the substrate structure (S10 of FIG. 1) and the laser beam. The (n+1)-th laser heat treatment may be performed in a raster scan manner while moving a stage on which the substrate structure (S10 in FIG. 1) is disposed. In the raster scan method, the laser beam may be scanned in one direction while moving the stage.

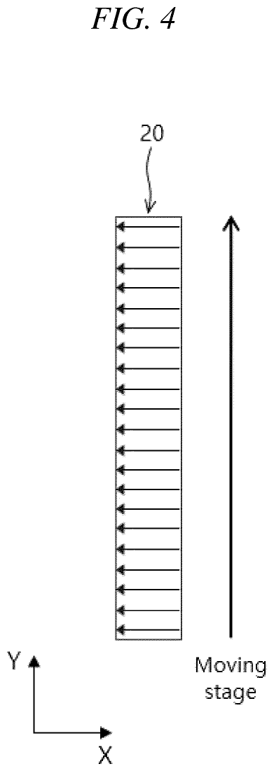

According to an example, the movement direction of the stage in FIG. 3 may be the opposite direction (i.e., the reverse direction) of the movement direction of the stage in FIG. 2. By reversing the direction of movement of the stage in the n-th laser heat treatment and the direction of movement of the stage in the (n+1)-th laser heat treatment, it may be possible to perform a more efficient process. However, this is exemplary, and the direction of movement of the stage in the n-th laser heat treatment and the direction of movement of the stage in the (n+1)-th laser heat treatment may be the same. An example of this is shown in FIG. 4.

FIG. 4 is a plan view to exemplarily illustrate a laser heat treatment method for the second region 20 of the substrate structure S10 of FIG. 1, according to another embodiment of the present invention.

Referring to FIG. 4, the step of performing the (n+1)-th laser heat treatment may comprise irradiating the second region 20 with the laser beam in a scanning manner while varying a relative position between the substrate structure (S10 of FIG. 1) and the laser beam. In this case, the direction of movement of the stage in the (n+1)-th laser heat treatment may be the same as the direction of movement of the stage in the n-th laser heat treatment described in FIG. 2.

Although not shown, the same or a similar method as the laser heat treatment method for the predetermined region as described in FIGS. 2 to 4 may be applied to the third region 30 of FIG. 1.

The laser beam used in the embodiments of the present invention described above may have a width (beam width), for example, in the range of about 1 μm to 500 μm. The laser beam may be, for example, any one of ultraviolet (e.g., EUV, DUV, UV), visible ray, infrared (IR), and microwave. The wavelength of the laser beam may be, for example, from about 0.01 μm to 11 μm. However, the specific types and wavelength ranges of the above laser beams are exemplary and may be varied in some cases. Furthermore, in an embodiment of the present invention, the substrate structure S10 may have an initial temperature of, for example, about 550 °C or less before performing the heat treatment using the laser beam, and the heating temperature of the corresponding region of the substrate structure S10 (the region irradiated by the laser) by irradiation of the laser beam may be in the range of, for example, about 200 °C to 3000 °C. However, the above temperature conditions are exemplary and may vary in some cases.

According to embodiments of the present invention, a laser heat treatment method may be implemented that may facilitate the control of temperature dispersion during heat treatment with a laser to improve heat treatment properties. Furthermore, embodiments of the present invention enable a laser heat treatment method that may simplify the optical system applied in heat treatment with a laser, thereby reducing equipment costs and reducing maintenance burden.

As the integration of semiconductor devices/electronic devices improves, the size of the unit device continues to shrink, and the process becomes more sophisticated, the temperature inhomogeneity generated on the substrate during laser heat treatment may cause various problems in the manufacturing characteristics of the device. In addition, in order to irradiate the laser in a constant shot area according to a stepper method in a conventional laser heat treatment process, it is necessary to ensure uniform laser energy over a relatively wide range to match the size of the shot area, which requires the application of a complex optical system. By applying a complex optical system, the cost of the equipment increases, and the maintenance and management of the equipment may also be disadvantageous.

However, according to an embodiment of the present invention, a laser beam having a small width (beam width) of about 1 μm to 500 μm may be used to heat treat a selected area in a scanning manner. Since the laser beam has a good uniformity, the method according to an embodiment of the present invention makes it possible to easily and favorably control the temperature dispersion occurring on the substrate. Furthermore, since the embodiments of the present invention utilize a scanning method of the laser beam, the optics may be greatly simplified compared to a conventional stepper method, and in this regard, the cost of the equipment may be reduced and the maintenance of the equipment may be significantly advantageous.

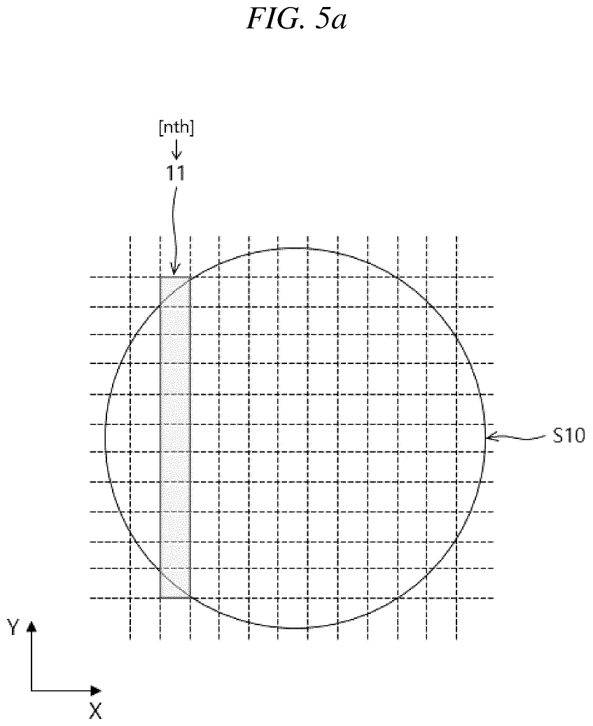

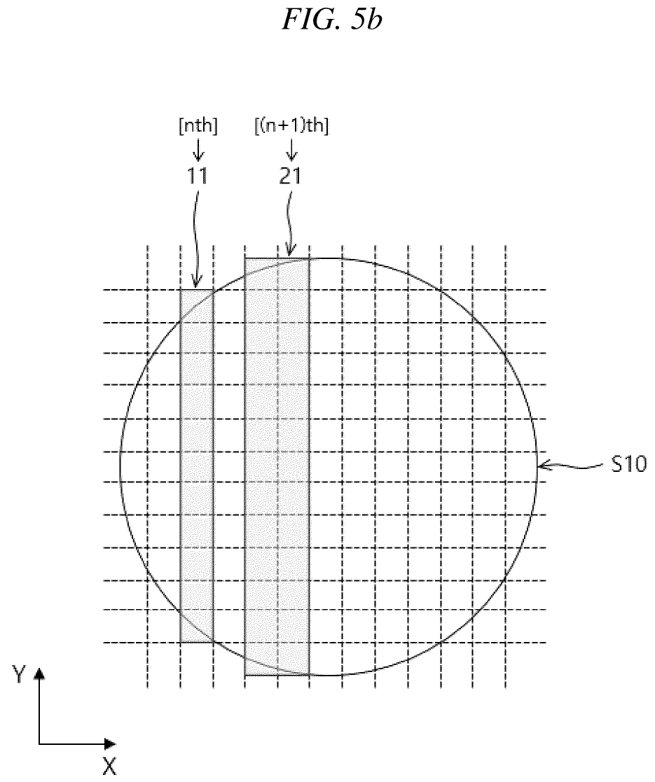

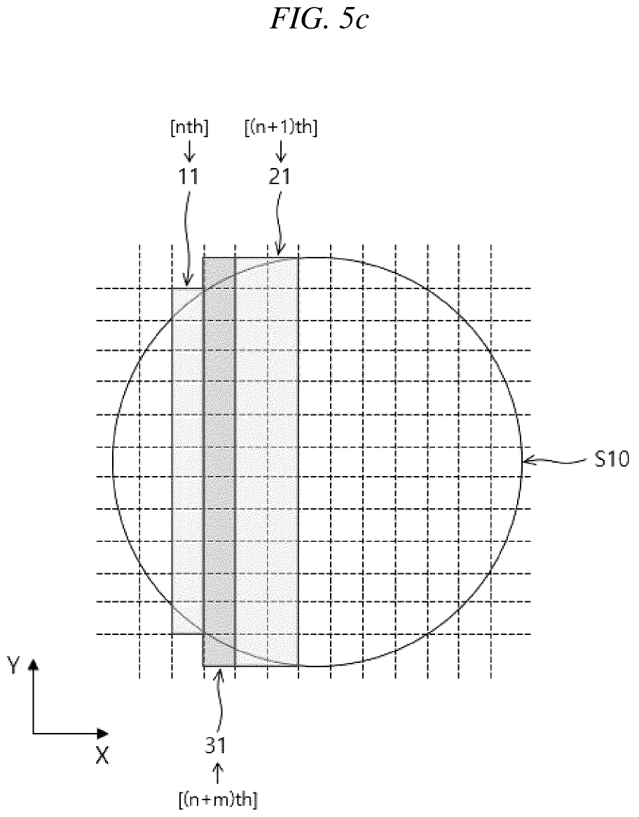

FIGS. 5a to 5c are plan views to illustrate a laser thermal treatment method for a substrate structure, according to another embodiment of the present invention.

Referring to FIG. 5a, a laser heat treatment method according to an embodiment may comprise the step of performing an n-th laser heat treatment on the substrate structure S10. The n-th laser heat treatment may be performed on a first region 11 comprising one or more the unit regions in the substrate structure S10. The step of performing the n-th laser heat treatment may comprise irradiating the first region (11) with the laser beam in a scanning manner while varying a relative position between the substrate structure (S10) and the laser beam. The n-th laser heat treatment may be performed in a raster scan manner while moving the stage on which the substrate structure S10 is disposed.

Referring to FIG. 5b, the laser heat treatment method may include the step of performing an (n+1)-th laser heat treatment on the substrate structure S10. The (n+1)-th laser heat treatment may be performed on a second region 21 comprising one or more of the unit regions in the substrate structure S10. The step of performing the (n+1)-th laser heat treatment may comprise irradiating the second region 21 with the laser beam in a scanning manner while varying a relative position between the substrate structure S10 and the laser beam. The (n+1)-th laser heat treatment may be performed in a raster scan manner while moving the stage on which the substrate structure S10 is disposed.

According to one embodiment, the first region 11 and the second region 21 may be mutually spaced apart. In other words, the n-th laser heat treatment and the (n+1)-th laser heat treatment may be spatially (regionally) spaced apart. In this way, when the the n-th laser heat treatment and the the (n+1)-th laser heat treatment are spatially (regionally) spaced apart, the effect of suppressing the temperature inhomogeneity of the substrate structure S10 in each laser heat treatment step may be improved.

Referring to FIG. 5c, the laser heat treatment method may include the step of performing an (n+m)-th laser heat treatment on the substrate structure S10. Here, the m may be an integer greater than 2. The (n+m)-th laser heat treatment may be performed on a third region 31 comprising one or more of the unit regions in the substrate structure S10. The step of performing the (n+m)-th laser heat treatment may comprise irradiating the third region 31 with the laser beam in a scanning manner while varying a relative position between the substrate structure S10 and the laser beam. The (n+m)-th laser heat treatment may be performed in a raster scan manner while moving the stage on which the substrate structure S10 is disposed.

The third region 31 may be located between the first region 11 and the second region 21. After performing the laser thermal treatment on each of the two spaced apart regions 11, 21, the laser thermal treatment may be performed on the third region 31 between the first region 11 and the second region 21 after a predetermined period of time. The third region 31 may be disposed to abut at least one of the first region 11 and the second region 21. Since the laser heat treatment of the third region 31 is performed after a given time has elapsed after performing the laser heat treatment of the first region 11 and the second region 21, a temperature change of the substrate structure S10 that occurs during the laser heat treatment of the first region 11 and the second region 21 may not affect the laser heat treatment of the third region 31.

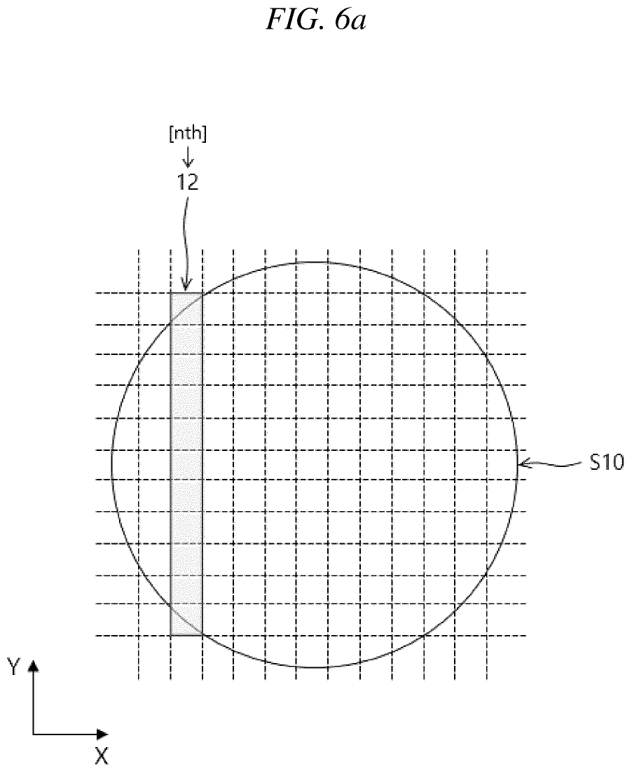

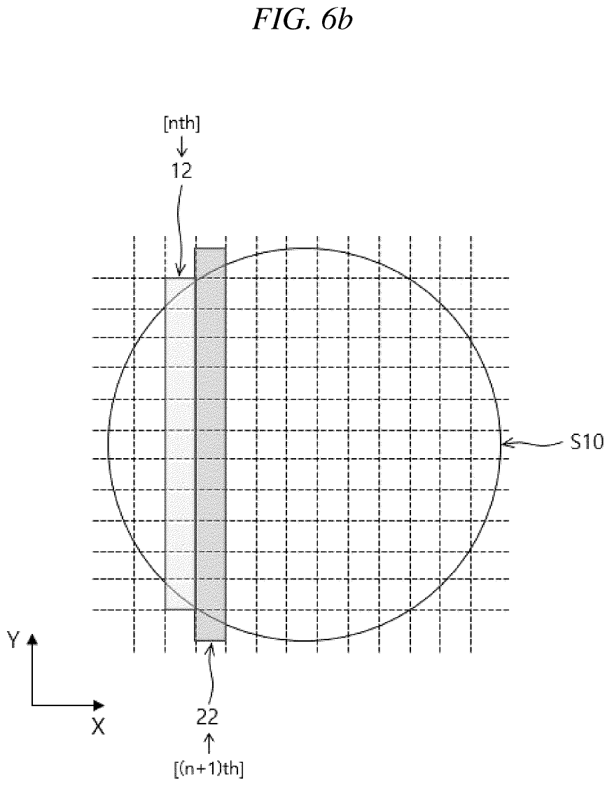

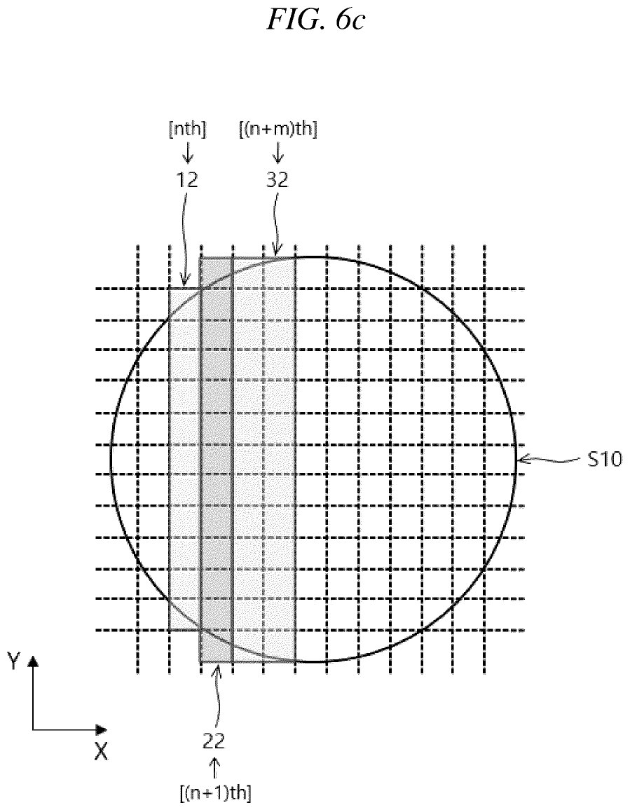

In the embodiment described with reference to FIGS. 5a to 5c, the first region 11 in which the n-th laser heat treatment is performed and the second region 21 in which the (n+1)-th laser heat treatment is performed are mutually spaced apart, but in some cases, the first region 11 in which the n-th laser heat treatment is performed and the second region 21 in which the (n+1)-th laser heat treatment is performed are mutually contacted. Here, “mutual contact” may include one-dimensional or two-dimensional joints, as well as joints that are partially overlapped. The case where the first region 11 and the second region 21 are in mutual contact will be described in more detail below with reference to FIGS. 6a through 6c.

FIGS. 6a through 6c are plan views to illustrate a method of laser heat treatment of a substrate structure, in accordance with another embodiment of the present invention.

Referring to FIG. 6a, a laser heat treatment method according to this embodiment may include the step of performing an n-th laser heat treatment on the substrate structure S10. The n-th laser heat treatment may be performed on a first region 12 comprising one or more the unit regions in the substrate structure S10. The step of performing the n-th laser heat treatment may comprise irradiating the first region 12 with the laser beam in a scanning manner while varying a relative position between the substrate structure S10 and the laser beam. The n-th laser heat treatment may be performed in a raster scan manner while moving the stage on which the substrate structure S10 is disposed.

Referring to FIG. 6b, the laser heat treating method may include the step of performing an (n+1)-th laser heat treatment on the substrate structure S10. The (n+1)-th laser heat treatment may be performed on a second region 22 comprising one or more of the unit regions in the substrate structure S10. The step of performing the (n+1)-th laser heat treatment may comprise irradiating the second region 22 with the laser beam in a scanning manner while varying a relative position between the substrate structure S10 and the laser beam. The (n+1)-th laser heat treatment may be performed in a raster scan manner while moving the stage on which the substrate structure S10 is disposed.

According to the present embodiment, the first region 12 and the second region 22 may be in contact with each other. Even if the first region 12 and the second region 22 are in mutual contact, after performing the laser heat treatment on the first region 12 by irradiating the laser beam in a scanning manner while changing the relative position between the substrate structure S10 and the laser beam, the laser heat treatment on the first region 12 is performed, laser heat treatment for the second region 22 is performed by irradiating the laser beam in a scanning manner while changing the relative position between the substrate structure S10 and the laser beam again, the effect of suppressing the temperature unevenness of the substrate structure S10 may be obtained.

Referring to FIG. 6c, the above laser heat treatment method may include the step of performing an (n+m)-th laser heat treatment on the substrate structure S10. Here, the m may be an integer greater than 2. The (n+m)-th laser heat treatment may be performed on a third region 32 comprising one or more of the unit regions in the substrate structure S10. The step of performing the (n+m)-th laser heat treatment may comprise irradiating the third region 32 with the laser beam in a scanning manner while varying a relative position between the substrate structure S10 and the laser beam. The (n+m)-th laser heat treatment may be performed in a raster scan manner while moving the stage on which the substrate structure S10 is disposed.

The third region 32 may be positioned to abut at least one of the first region 12 and the second region 22. For example, the third region 32 may be in contact with the second region 22. In this case, the second region 22 may be positioned between the first region 12 and the third region 32. Even if the second region 22 and the third region 32 are in contact with each other, after performing the laser heat treatment on the second region 22 by irradiating the laser beam in a scanning manner while varying the relative position between the substrate structure S10 and the laser beam, If laser heat treatment for the third region 32 is performed by irradiating the the laser beam in a scanning manner while changing the relative position between the substrate structure S10 and the the laser beam again, the effect of suppressing the temperature unevenness of the substrate structure S10 may be obtained.

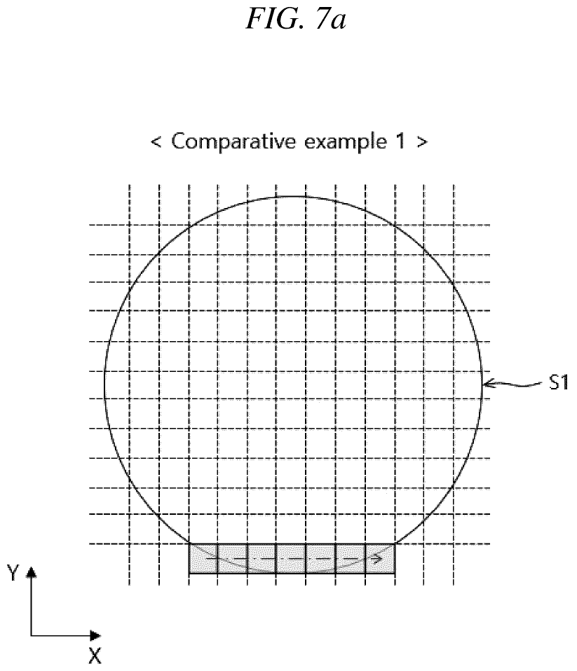

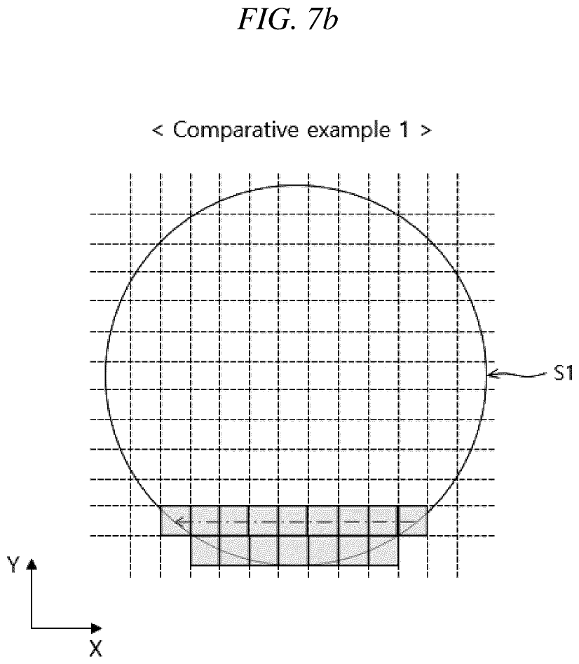

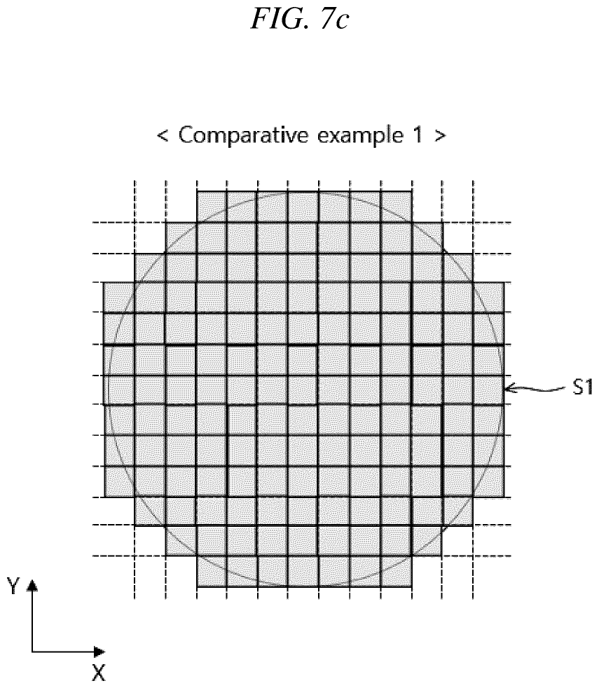

FIGS. 7a to 7c are plan views for illustrating a laser heat treatment method for a substrate structure according to the first comparative example.

Referring to FIGS. 7a to 7c, in the laser heat treatment method according to the first comparative example, a first laser heat treatment (i.e., laser shot) may be performed on a first region (first unit region) of the substrate structure S1, and then a second laser heat treatment (i.e., laser shot) may be performed on the second unit region by moving to a second unit region bordering the first unit region. The laser heat treatment may be performed in a shot fashion over the entire area of the substrate structure S1 by moving to the next area (unit area) bordering the previous laser heat treatment area. Starting from the lower left edge of the illustrated substrate structure S1, the laser heat treatment may be performed while moving and aligning repeatedly. As such, when the n-th laser heat treatment area and the (n+1)-th laser heat treatment area are mutually contiguous, the n-th laser heat treatment area and the (n+1)-th laser heat treatment area may not be heat treated under the same temperature condition because the substrate temperature condition of the areas adjacent to the n-th laser heat treatment area changes during the heat treatment of the n-th laser heat treatment area. In this regard, the peak temperature in the n-th laser heat treatment zone and the peak temperature in the (n+1)-th laser heat treatment zone may be different. Furthermore, temperature variations may also occur within the n+1th laser heat treatment zone. This temperature non-uniformity may result in non-uniformity and degradation of the properties of the device.

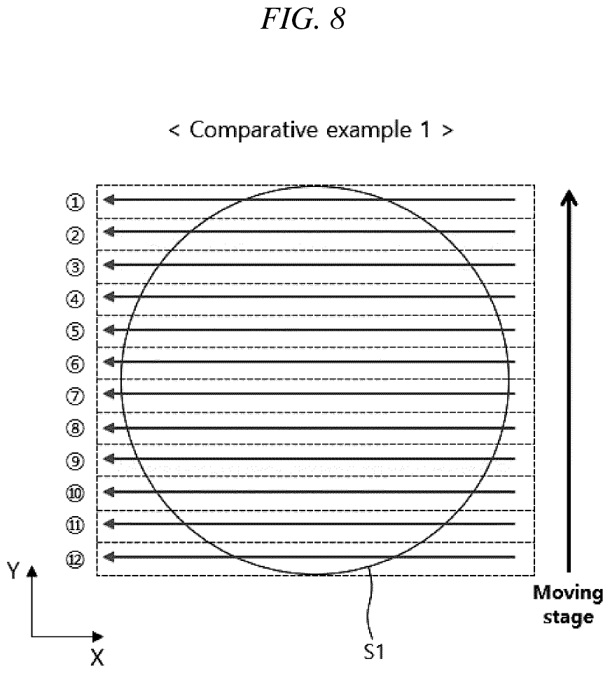

FIG. 8 is a plan view to illustrate a laser thermal treatment method for a substrate structure, according to a second comparative example.

Referring to FIG. 8, in the laser heat treatment method according to the second comparative example, a first laser scan may be performed on one line region (first line region) of the substrate structure S1, and then a second laser scan may be performed on a second line region bordering the first line region. By moving to the next area bordering the previous laser scan area, laser heat treatment according to the scanning method may be performed on the entire area of the substrate structure S1. Starting from the upper region of the substrate structure S1 in the drawing, the laser scan may be performed by moving and aligning repeatedly. The red arrow indicates the scan direction of the area where the laser heat treatment was performed, and the number written to the left of the arrow is the laser scan sequence.

As in the second comparative example above, performing laser annealing on the entire substrate structure S1 in one continuous process increases the likelihood of unwanted overheating of the lower side of the substrate structure S1 and/or unwanted temperature unevenness on the upper side of the substrate structure S1 (i.e., the upper surface irradiated by the laser beam). In particular, if the lower side of the substrate structure S1 is overheated, an element such as a transistor or diode pre-formed on the lower side may be damaged by heat or deteriorate in performance. As a result, the characteristics of the device to be finally manufactured from the substrate structure S1 may be deteriorated, the defect rate may increase, and other problems may occur.

A method for manufacturing an electronic device (semiconductor device) according to an embodiment of the present invention may include a step of heat treating a substrate structure using a laser heat treatment method according to the aforementioned embodiments, and a step of forming an electronic device (semiconductor device) from the heat treated substrate structure. The step of forming the electronic device (semiconductor device) from the heat-treated substrate structure may include, for example, the step of performing a finishing process on the substrate structure, the step of dicing the substrate structure to form a plurality of device parts, and the step of packaging the plurality of device parts. As the above finishing process, dicing process, packaging process, etc. may be well known in the art, a detailed description thereof will be omitted.

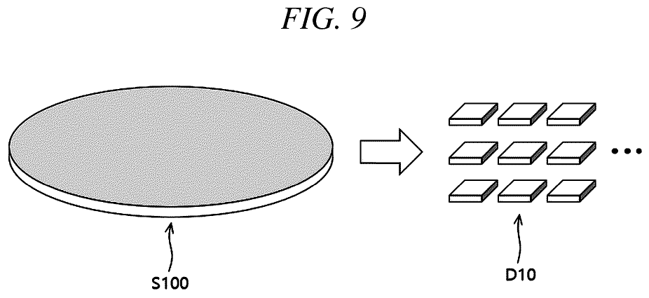

FIG. 9 is a perspective view to illustrate a method of manufacturing an electronic device by applying a laser heat treatment method to a substrate structure according to an embodiment of the present invention.

Referring to FIG. 9, a plurality of devices D10 may be formed from the heat-treated substrate structure S100. The plurality of devices D10 may be electronic devices (semiconductor devices). The elements D10 may be memory elements or non-memory elements.

According to the embodiments of the present invention described above, a laser heat treatment method may be implemented that may facilitate control of temperature dispersion during heat treatment with a laser to improve heat treatment characteristics. Furthermore, according to embodiments of the present invention, a laser heat treatment method may be implemented that may simplify the optical system applied in heat treatment with a laser, thereby reducing equipment costs and reducing the maintenance burden. By applying a laser heat treatment method according to embodiments of the present invention, it may be possible to manufacture electronic devices (semiconductor devices) having excellent performance and uniformity.

Preferred embodiments of the present invention have been disclosed herein, and although certain terms are used, they are used in a general sense only to facilitate the description and understanding of the invention, and are not intended to limit the scope of the invention. In addition to the embodiments disclosed herein, other modifications based on the technical ideas of the present invention will be apparent to those of ordinary skill in the art to which the present invention belongs. One having ordinary knowledge in the art will recognize that the method of laser heat treatment of a substrate structure according to the embodiments described with reference to FIGS. 1 to 6c and FIG. 9, and the method of manufacturing an electronic device thereof, may be variously substituted, altered, and modified without departing from the technical idea of the invention. The scope of the invention is therefore not to be defined by the embodiments described, but by the technical idea recited in the patent claims.

### INDUSTRIAL APPLICABILITY

Embodiments of the present invention may be applied to methods of heat treatment of a workpiece and to the manufacture of devices using the same. Embodiments of the invention may be applied to methods of laser heat treatment of substrate structures and to the manufacture of electronic devices using the same.

1. A method of laser heat treatment for performing thermal treatment on one surface of a substrate structure that is dividable into a plurality of unit regions, comprising:
performing an n-th laser annealing on the substrate structure, and
performing an (n+1)-th laser annealing on the substrate structure,
wherein the n-th laser annealing is performed on a first region of the substrate structure including one or more of the unit regions, and the (n+1)-th laser annealing is performed on a second region of the substrate structure including one or more of the unit regions,
wherein performing the n-th laser annealing comprises scanning a laser beam over the first region while changing a relative position between the substrate structure and the laser beam,
(n+1)-th laser annealing comprises scanning the laser beam over the second region while changing the relative position between the substrate structure and the laser beam,
wherein performing the (n+1)-th laser annealing comprises scanning the second region with the laser beam while changing the relative position between the substrate structure and the laser beam.

2. The method of claim 1, wherein each of the n-th laser heat treatment and the (n+1)-th laser heat treatment is performed in a raster scan manner while moving a stage on which the substrate structure is disposed.

3. The method of claim 1, wherein a scan direction width of the laser beam of each of the first region and the second region is smaller than a scan-direction width of the substrate structure.

4. The method of claim 1, wherein the first region and the second region are spaced apart from each other.

5. The method of claim 4, wherein the plurality of unit regions are arranged to form a plurality of rows in a first direction and a plurality of columns in a second direction perpendicular to the first direction,
wherein the first region and the second region are spaced apart from each other in any one of the first direction, the second direction, and a third direction between the first direction and the second direction.

6. The method of claim 5, wherein a spacing between the first region and the second region is at least 90% of a width of the unit region in either the first direction or the second direction.

7. The method of claim 1, wherein the first region and the second region are in contact with each other.

8. The method of claim 1, wherein the first region and the second region have different sizes.

9. The method of claim 1, wherein the first region and the second region have the same size.

10. The method of claim 1,
wherein the laser heat treatment method comprises the step of performing an (n+m)-th laser heat treatment on the substrate structure, wherein m is an integer greater than 2, and
wherein the (n+m)-th laser heat treatment is performed on a third region of the substrate structure, and
wherein the third region is located on one side of any one of the first region and the second region, or is located between the first region and the second region.

11. The method of claim 1, wherein the laser heat treatment method is performed over the entire effective area of the one surface of the substrate structure.

12. The method of claim 1, wherein the laser beam has a width in the range of 1 μm to 500 μm.

13. The method of claim 1, wherein the laser beam comprises any one of ultraviolet ray, visible ray, infrared ray, and microwave.

14. The method of claim 1, wherein the substrate structure comprises a semiconductor film or an insulator film, and wherein the heat treatment with a laser is performed to change the crystallinity, physical properties, or film quality of the semiconductor film or insulator film.

15. The method of claim 1, wherein the substrate structure comprises a wafer.

16. The method of claim 1, wherein before performing the heat treatment with the laser beam, the substrate structure has an initial temperature of 550 °C or less, and
wherein the heating temperature of a corresponding region of the substrate structure by irradiation of the laser beam is in the range of 200 to 3000 °C.

17. A method of manufacturing an electronic device, comprising:
heat treating a substrate structure using the laser heat treatment method of claim 1 and manufacturing an electronic device from the heat-treated substrate structure.
